(19) United States
(12) Patent Application Publication
(10) Pub. No.: US 2012/0051113 A1
(43) Pub. Date: Mar. 1, 2012

(54) SEMICONDUCTOR INTEGRATED CIRCUIT

(76) Inventors: Min-Seok CHOI, Gyeonggi-do (KR); Jong-Chern Lee, Gyeonggi-do (KR)

(21) Appl. No.: 12/945,120

(22) Filed: Nov. 12, 2010

(30) Foreign Application Priority Data
Aug. 27, 2010 (KR) 10-2010-0083457

(51) Int. Cl. G11C 5/02; G11C 5/06; H01L 21/50

(52) U.S. Cl. 365/51; 438/109; 257/E21.499

(57) ABSTRACT

A semiconductor integrated circuit includes a plurality of slave chips each including a core area including a memory cell array, a global data line configured to transfer input/output data of the corresponding core area, and a first peripheral circuit area configured to interface the corresponding core area and the corresponding global data line, a plurality of data transfer through-chip vias vertically formed through the plurality of slave chips, respectively, and coupled to the respective global data lines of the slave chips, and a master chip including a second peripheral circuit area configured to provide an input/output interface between the data transfer through-chip vias and an external controller.

### CROSS-REFERENCE TO RELATED APPLICATION

The present application claims priority of Korean Patent Application No. 10-2010-0083457, filed on Aug. 27, 2010, which is incorporated herein by reference in its entirety.

### BACKGROUND OF THE INVENTION

Exemplary embodiments of the present invention relate to semiconductor design technology, and more particularly, to a semiconductor integrated circuit.

In general, packaging technology for semiconductor integrated circuits has been continuously developed to satisfy demands for miniaturization and mounting reliability. Recently, as the high performance of electrical and electronic products has been requested with the miniaturization of electrical and electronic products, a variety of technologies for producing a stack package have been developed.

In the semiconductor industry, “stack” refers to vertically stacking at least two or more semiconductor chips or packages. When a semiconductor device utilizes a stack package, it may obtain a memory capacity two or more times larger than a semiconductor device that does not utilize a stack package. Furthermore, the stack package not only increases the memory capacity, but is also advantageous with regards to the packaging density and the efficient use of the mounting area.

The stack package may be fabricated by the following methods. First, individual semiconductor chips may be stacked, and then packaged at once. Second, packaged individual semiconductor chips may be stacked. The individual semiconductor chips of the stack package are electrically coupled through metallic wires or through-chip vias. The stack package using through-chip vias has a structure in which the physical and electrical coupling between semiconductor chips is vertically achieved by through-chip vias formed in the respective semiconductor chips.

FIG. 1 is a diagram illustrating a through-chip via.

Referring to FIG. 1, a hole is formed through a semiconductor chip A, and a through-chip via B is formed by filling the hole with a metal having an excellent conductivity, for example, Cu. Then, the semiconductor chip A is stacked onto a semiconductor chip C. A plurality of semiconductor chips A may be stacked to form a semiconductor integrated circuit, which is typically referred to as a three-dimensional (3D) stack package semiconductor integrated circuit.

FIG. 2 is a perspective view of a 3D stack package semiconductor integrated circuit.

The 3D stack package of FIG. 2 includes, for example, four semiconductor chips.

Referring to FIG. 2, the 3D stack package semiconductor integrated circuit (hereafter, referred to as the “semiconductor integrated circuit”) 100 includes first to fourth semiconductor chips 110 to 140 and first to third through-chip vias 150 to 170. The first to fourth semiconductor chips 110 to 140 are stacked vertically, and the first to third through-chip vias 150 to 170 are formed through the second to fourth semiconductor chips 120 to 140, respectively, and configured to interface data signals and power supply signals among the first to fourth semiconductor chips 110 to 140.

Among the first to fourth semiconductor chips 110 to 140, the first semiconductor chip 110 positioned at the lowermost portion is typically referred to as a master chip. The master chip is configured to buffer an external signal applied from outside, for example, from a controller and control the second to fourth semiconductor chips 120 to 140 through the first to third through-chip vias 150 to 170. The second to fourth semiconductor chips 120 to 140, which are controlled by the master chip, are typically referred to as slave chips.

The first to third through-chip vias 150 to 170 are provided only in the slave chips, that is, the second to fourth semiconductor chips 120 to 140, respectively. This is because circuits are formed on the upper surfaces of the first to fourth semiconductor chips 110 to 140. The first to third through-chip vias 150 to 170 may be through silicon vias (TSV). FIG. 2 illustrates that each of the slave chips includes only one through-chip via. In reality, however, the slave chips typically include at least several hundred to several thousand through-chip vias.

FIG. 3 is a side view illustrating the semiconductor integrated circuit 100 of FIG. 2 in more detail. FIG. 3 is a conceptual diagram of the semiconductor integrated circuit 100.

The first to fourth semiconductor chips 110 to 140 include core areas 112 to 142 and peripheral circuit areas 114 to 144, respectively. The core areas 112 to 142 include a memory cell array, and the peripheral circuit areas 114 to 144 include a variety of circuits configured to read or write data through the core areas 112 to 142 in response to a command. In other words, since the same mask process is used, the first to fourth semiconductor chips 110 to 140 are fabricated in such a manner as to have the same internal circuits and layout. Accordingly, the first to fourth semiconductor chips 110 to 140 are designated as either the master chip or one of the slave chips depending on their roles. That is, as described above, the first semiconductor chip 110, which is positioned at the lowermost portion to interface data signals or power supply signals with the outside, serves as the master chip, and the second to fourth semiconductor chips 120 to 140, which are stacked on the first semiconductor chip 110 and controlled by the first semiconductor chip 110, serve as the slave chips.

The first to third chip-through vias 150 170 are vertically formed through the second to fourth peripheral circuit areas 124 to 144 included in the second to fourth semiconductor chips 120 to 140, respectively, and are configured to interface data signals and power supply signals among the first to fourth semiconductor chips 110 to 140.

However, the above-described semiconductor integrated circuit 100 raises the following issue.

As described above, the first to fourth semiconductor chips 110 to 140 are fabricated according to the same mask process. Furthermore, the four semiconductor chips fabricated in the same manner are stacked, and then designated as the master chip and the slave chips depending on the roles thereof. Accordingly, various circuits used by the master chip are duplicated and provided in the slave chips (e.g., in the second to fourth semiconductor chips 120 to 140). Therefore, circuits which are not used by the slave chips unnecessarily occupy an area in the slave chips. This may reduce net die per wafer.

Furthermore, the first to fourth semiconductor chips 110 to 140 are fabricated by the same mask process. Therefore, when a fail caused by the mask process occurs, all the semiconductor chips should be replaced. Accordingly, the yield of the semiconductor integrated circuit 100 decreases, and thus, a fabricating cost may increase.

### SUMMARY OF THE INVENTION

Exemplary embodiments of the present invention are directed to a semiconductor integrated circuit of which the area is optimized.

Further, exemplary embodiments of the present invention are directed to a semiconductor integrated circuit, including a master chip and slave chips which are fabricated by different mask processes.

In accordance with an exemplary embodiment of the present invention, a semiconductor integrated circuit includes a plurality of slave chips each including a core area including a memory cell array, a global data line configured to transfer input/output data of the corresponding core area, and a first peripheral circuit area configured to interface the corresponding core area and the corresponding global data line, a plurality of data transfer through-chip vias vertically formed through the plurality of slave chips, respectively, and coupled to the respective global data lines of the slave chips, and a master chip including a second peripheral circuit area configured to provide an input/output interface between the data transfer through-chip vias and an external controller. Each of the slave chips does not include the second peripheral circuit area.

In accordance with another exemplary embodiment of the present invention, a semiconductor integrated circuit includes a plurality of slave chips each including a first core area including a memory cell array, a first global data line configured to transfer input/output data of the corresponding first core area, and a first peripheral circuit area configured to interface the corresponding first core area with the corresponding first global data line, a plurality of data transfer through-chip vias vertically formed through the plurality of slave chips, respectively, and coupled to the respective global data lines of the slave chips, and a master chip including a second core area including a memory cell array, a second global data line configured to transfer input/output data of the second core area, a second peripheral circuit area configured to interface the second core area with the second global data line, and a third peripheral circuit area configured to provide an input/output interface between the second global data line and an external controller and an input/output interface between the plurality of data transfer through-chip vias and the external controller. Each of the slave chips does not include the third peripheral circuit area.

In accordance with yet another exemplary embodiment of the present invention, a semiconductor integrated circuit includes a master chip including a master peripheral circuit area, and a slave chip, stacked onto the master chip, including a core area including a memory cell array, a global data line configured to transfer input/output data of the core area, and a slave peripheral circuit area configured to interface the core area and the global data line, and a data transfer through-chip via vertically formed through the slave chip, and coupled to the global data line of the slave chip, wherein the area of the master peripheral circuit area is greater than the area of the slave peripheral circuit area.

In accordance with still another exemplary embodiment of the present invention, a method for fabricating a semiconductor integrated circuit includes forming a master chip, including a master peripheral circuit area, using a master chip mask, forming a slave chip, including a core area and a slave peripheral circuit area, using a slave chip mask, stacking the slave chip onto the master chip, wherein the area of the slave peripheral circuit area is greater than the area of the master peripheral circuit area.

### BRIEF DESCRIPTION OF THE DRAWINGS

FIG. 1 is a diagram illustrating a through-chip via.

FIG. 2 is a perspective view of a general 3D stack package semiconductor integrated circuit.

FIG. 3 is a side view illustrating the semiconductor integrated circuit 100 of FIG. 2 in more detail.

FIG. 4 is a side view of a semiconductor integrated circuit in accordance with a first exemplary embodiment of the present invention.

FIG. 5 is a block diagram illustrating a first master peripheral circuit area included in a master chip of FIG. 4.

FIGS. 6A and 6B are block diagrams illustrating a second master peripheral circuit area included in the master chip of FIG. 4.

FIG. 7 is a side view of a semiconductor integrated circuit in accordance with a second exemplary embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

In accordance with the exemplary embodiments of the present invention described herein, a 3D stack package semiconductor integrated circuit (hereafter, referred to as the “semiconductor integrated circuit”) includes one master chip and three slave chips. However, other exemplary embodiments wherein the semiconductor integrated circuit includes more or less slave chips are contemplated, and therefore, are within the scope of the invention.

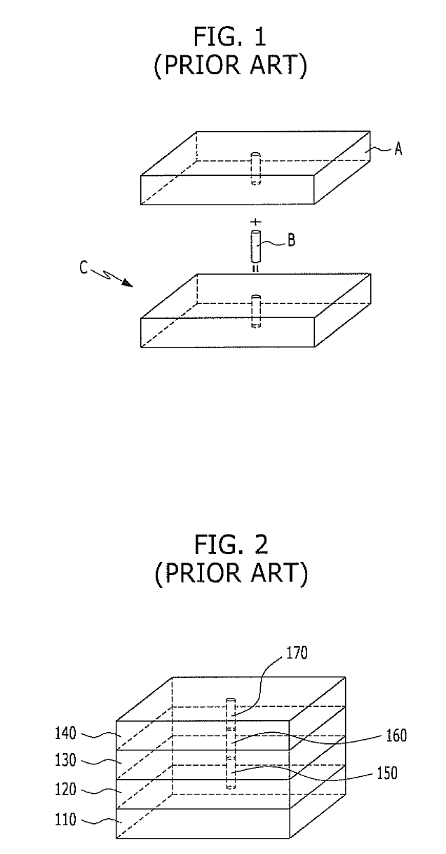

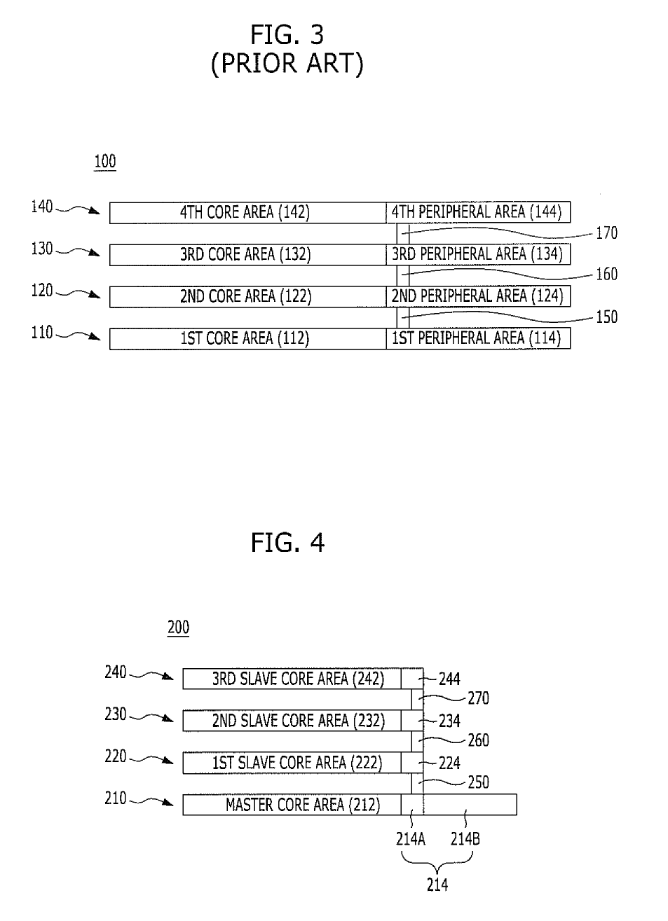

FIG. 4 is a side view of a semiconductor integrated circuit in accordance with a first exemplary embodiment of the present invention. The side view of the semiconductor integrated circuit is a conceptual diagram. The semiconductor integrated circuit is constructed in such a manner as illustrated in FIGS. 1 and 2.

Referring to FIG. 4, the semiconductor integrated circuit 200 includes a master chip 210, first to third slave chips 220 to 240, and first to third data transfer through-chip vias 250 to 270. The master chip 210 is positioned in the lowermost portion of the semiconductor integrated circuit and configured to interface a variety of signals with an external controller, which is not illustrated. The first to third slave chips 220 to 240 are vertically stacked over the master chip 210 and operated according to control signals transmitted by the master chip 210. The first to third data transfer through-chip vias 250 to 270 are vertically formed through the first to third slave chips 220 to 240, respectively, and configured to interface input/output data between the master chip 240 and the first to third slave chips 220 to 240.

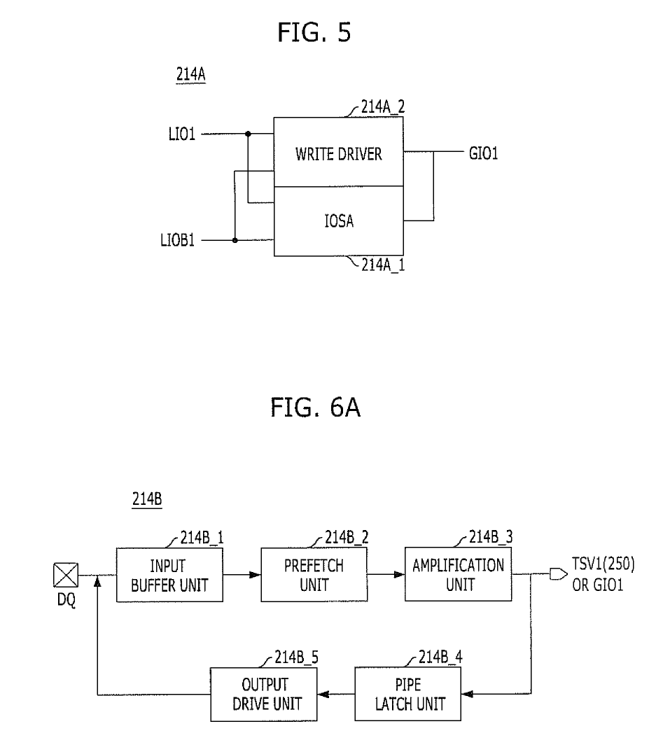

The master chip 210 includes a master core area 212, a master global data line GIO1 (see FIG. 5), and a master peripheral circuit area 214. The master core area 212 includes a memory cell array, and the master global data line GIO1 is configured to interface input/output data between the master core area 212 and the master peripheral circuit area 214. The master peripheral circuit area 214 includes a first master peripheral circuit area 214A and a second master peripheral circuit area 214B. The first master peripheral circuit area 214A is configured to interface the master core area 212 and the master global data line GIO1. The second master peripheral circuit area 214B is configured to provide an input/output interface between the master global data line GIO1 and the external controller and an input/output interface between the first to third data transfer through-chip vias 250 to 270 and the external controller.

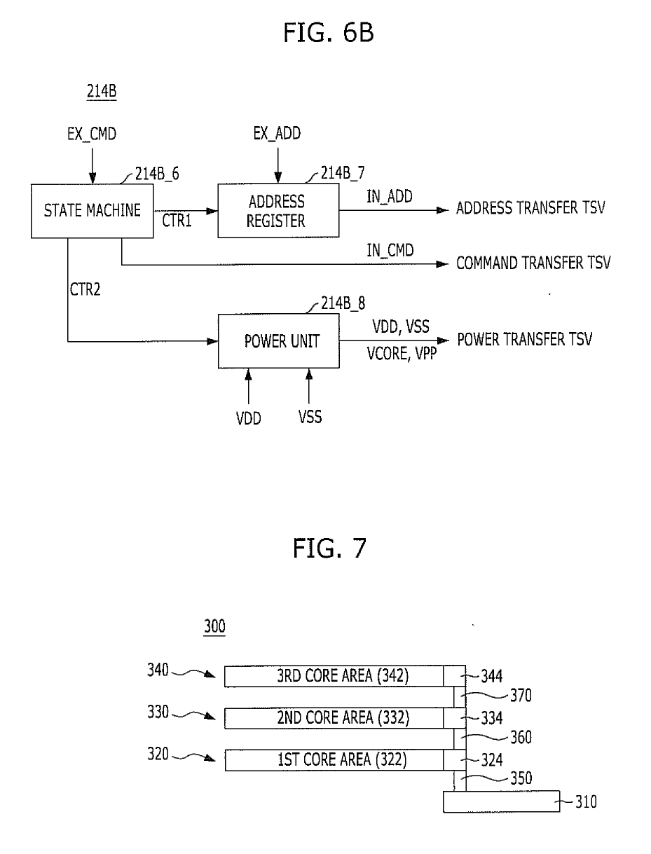

FIG. 5 is a block diagram illustrating the first master peripheral circuit area 214A of FIG. 4. FIGS. 6A and 6B are block diagrams illustrating the second master peripheral circuit area 214B of FIG. 4.

First, referring to FIG. 5, the first master peripheral circuit area 214A includes a sense amplification unit 214A_1 and a write driver 214A_2. The sense amplification unit 214A_1 is configured to amplify data loaded onto master local data lines LIO1 and LIOB1 included in the master core area 212, and transfer the amplified data to the master global data line GIO1. The write driver 214A_2 is configured to drive the master local data lines LIO1 and LIOB1 in response to the data loaded onto the master global data line GIO1.

Referring to FIG. 6A, the second master peripheral circuit area 214B includes an input circuit and an output circuit. The input circuit includes an input buffer unit 214B_1, a prefetch unit 214B_2, and an amplification unit 214B_3. The input buffer unit 214B_1 is configured to buffer data inputted through a data pad DQ. The prefetch unit 214B_2 is configured to prefetch the data buffered by the input buffer unit 214B_1. The amplification unit 214B_3 is configured to amplify the data prefetched by the prefetch unit 214B_2 and output the amplified data to the master global data line GIO1 or the first to third data transfer through-chip vias 250 to 270. The output circuit includes a pipe latch unit 214B_4 and an output drive unit 214B_5. The pipe latch unit 214B_4 is configured to latch the data transferred through the master global data line GIO1 or the first to third data transferred through-chip vias 250 to 270. The output drive unit 214B_5 is configured to output the data latched in the pipe latch unit 214B_4 to the data pad DQ. The output driver 214B_5 includes a main driver and a pre-driver.

Meanwhile, the second master peripheral circuit area 214B further includes a variety of circuits required for the master chip. That is, referring to FIG. 6B, the second master peripheral circuit area 214B further includes a state machine 214B_6, an address register 214B_7, and a power unit 214B_8. The state machine 214B_6 is configured to internally process an external command EX_CMD inputted from outside and transfer an internal command IN_CMD to the first to third slave chips 220 to 240 through command transfer through-chip vias which are not illustrated. The address register 214B_7 is configured to receive an address EX_ADD from outside, latch the received address, and transfer the latched address IN_ADD to the first to third slave chips 220 to 240 through address transfer through-chip vias in response to a first control signal CTR1 supplied by the state machine 214B_6. The address transfer through-chip vias are not illustrated. The power unit 214B_8 is configured to receive external voltages VDD and VSS, generate internal voltages VCORE and VPP, and transfer the corresponding voltages VDD, VSS, VCORE, and VPP to the first to third slave chips 220 to 240 through power transfer through-chip vias in response to a second control signal CTR2 supplied by the state machine 214B_6. The power transfer through-chip vias are not illustrated. Furthermore, although not illustrated in the drawing, the second master peripheral circuit area 214B may further include a master test circuit configured to test whether the master chip 210 normally operates or not.

Referring to FIG. 4, the first to third slave chips 220 to 240 include first to third slave core areas 222 to 242, first to third slave global data lines GIO2_1 to GIO2_3 which are not illustrated, and first to third slave peripheral circuit areas 224 to 244, respectively. The first to third slave core areas 222 to 242 include a memory cell array. The first to third slave global data lines GIO2_1 to GIO2_3 are configured to transfer input/output data of the first to third slave core areas 222 to 242. The first to third slave peripheral circuit areas 224 to 244 are configured to interface the first to third slave core areas 222 to 242 and the first to third slave global data lines GIO2_1 to GIO2_3, respectively.

At this time, the first to third slave peripheral circuit areas 224 to 244 are configured in the same manner as the above-described first master peripheral circuit area 214A (see FIG. 5). Because the first to third slave peripheral circuit areas 224 to 244 include less circuitry, it is possible to optimize the area of the first to third slave chips 220 to 240. For example, the areas of the first to third slave chips 220 to 240 may be reduced as much as the area of the second master peripheral circuit area 214B.

Although not shown in FIG. 4, the first to third slave peripheral circuit areas 224 to 244 may further include slave test circuits configured to test whether the first to third slave chips 220 to 240 normally operate or not. The slave test circuits may be test circuits suitable for the configuration of the respective slave chips 220 to 240. That is, test circuits capable of performing a test in a low-frequency environment may be used. Such test circuits may require less area than the test circuit of the master chip 210. For example, a built-in self test (BIST) circuit may be used as the slave test circuit.

The first to third data transfer through-chip vias 250 to 270 are coupled to the respective slave global data lines GIO2-1 to GIO2_3 of the first to third slave chips 220 to 240, and transfer input/output data between the respective slave global data lines GIO2_1 to GIO2_3 and the master peripheral circuit area 214. That is, the first to third data transfer through-chip vias 250 to 270 essentially function as extended lines of the respective slave global data lines GIO2_1 to GIO2_3. The first to third data transfer through-chip vias 250 to 270 may be through silicon vias (TSVs).

In accordance with the first exemplary embodiment of the present invention, the respective slave peripheral circuit areas 224 to 244 of the first to third slave chips 220 to 240 include less circuitry than the master peripheral circuit area 214, which includes both the first master peripheral circuit area 214A and the second master peripheral circuit area 214B. Therefore, it is possible to minimize the entire area of the semiconductor integrated circuit 200.

In the semiconductor integrated circuit 200 in accordance with the first exemplary embodiment of the present invention, the peripheral circuits included in the master chip 210 are configured in a different manner from those included in the first to third slave chips 220 to 240. Therefore, the master chip 210 and the first to third slave chips 220 to 240 are fabricated by different mask processes. Accordingly, because the master chip 210 and the first to third slave chips 220 to 240 are separately fabricated (i.e., different mask processes are used), an error in the fabrication of the master chip 210 may not affect the fabrication of the first to third slave chips 220 to 240 and vice versa. Therefore, the yield of the semiconductor integrated device 200 may be improved.

FIG. 7 is a side view of a semiconductor integrated circuit in accordance with a second exemplary embodiment of the present invention. The side view of the semiconductor integrated circuit in accordance with the second exemplary embodiment of the present invention is a conceptual diagram, similar to the first exemplary embodiment of the present invention.

In accordance with the second embodiment of the present invention, even the area of a master chip may be optimized.

Referring to FIG. 7, the semiconductor integrated circuit 300 includes a master chip 310, first to third slave chips 320 to 340, and first to third data transfer through-chip vias 350 to 370. The first to third slave chips 320 to 340 are vertically stacked, and the first to third data transfer through-chip vias 350 to 370 are vertically formed through the first to third slave chips 320 to 340, respectively.

Here, the master chip 310 includes only a master peripheral circuit area. The master peripheral circuit area includes input and output circuits configured to provide an input/output interface between the first to third data transfer through-chip vias 350 to 370 and an external controller which is not illustrated in FIG. 7 (see FIG. 6A). Furthermore, the master peripheral circuit area may include a variety of circuits required for the master chip 310. For example, the master peripheral circuit area may include a power unit configured to interface power and a state machine configured to process an address and command inputted from outside (see FIG. 6B). Furthermore, the master peripheral circuit area may further include a master test circuit configured to test whether the master chip 310 normally operates or not.

The first to third slave chips 320 to 340 include first to third core areas 322 to 342, first to third global data lines which are not illustrated in FIG. 7, and first to third slave peripheral circuit areas 324 to 344, respectively. The first to third core areas 322 to 342 include a memory cell array. The first to third global data lines are configured to transfer input/output data of the first to third core areas 322 to 342. The first to third slave peripheral circuit areas 324 to 344 are configured to interface the first to third core areas 322 to 342 and the first to third global data lines. In particular, the first to third slave peripheral circuit areas 324 to 344 include a minimum number of peripheral circuits required for the slave chips (see FIG. 5). The first to third slave peripheral circuit areas 324 to 344 may further include slave test circuits configured to test whether the first to third slave chips 320 to 340, respectively, operate or not. The slave test circuits may be test circuits suitable for the configuration of the respective slave chips 320 to 340. For example, BIST circuits may be used.

The first to third data transfer through-chip vias 350 to 370 are coupled to the respective global data lines included in the first to third slave chips 320 to 340, and transfer input/output data between the respective global data lines and the master chip 310. That is, the first to third data transfer through-chip vias 350 to 370 essentially function as extended lines of the respective global data lines. The first to third data transfer through-chip vias 350 to 370 may be through silicon vias (TSVs).

In accordance with the second exemplary embodiment of the present invention, the master peripheral circuit area and the first to third slave peripheral circuit areas 324 to 344 do not include unnecessary circuitry for inputting and outputting data with an outside of the semiconductor integrated circuit 300. In the semiconductor integrated circuit 300, the configuration of the master chip 310 is different from those of the first to third slave chips 320 to 340. Accordingly, the master chip 310 and the first to third slave chips 320 to 340 are fabricated by using different mask processes from each other.

In accordance with the second exemplary embodiment of the present invention, the overall areas of the master chip and the slave chips may be reduced in comparison with those of the conventional semiconductor integrated chip. In particular, as the area of the master chip is reduced, an extra area is obtained in which additional peripheral circuits for improving the performance of the semiconductor integrated circuit may be implemented. Furthermore, as the master chip and the slave chips are fabricated using separate mask processes, fabrication of the master chip does not affect the fabrication of the slave chips and vice versa. Therefore, it is possible to reduce the number of chips that fail as a result of a single fabrication error.

In accordance with the exemplary embodiments of the present invention, the semiconductor integrated circuit is fabricated in such a manner that the master chip and the slave chips have a reduced number of circuits. Therefore, net die per wafer may be increased to improve the yield of the respective chips.

Furthermore, the yield of the semiconductor integrated circuit may increase, and a fabrication cost may be reduced.

While the present invention has been described with respect to the specific embodiments, it will be apparent to those skilled in the art that various changes and modifications may be made without departing from the spirit and scope of the invention as defined in the following claims.

For example, only the data transfer through-chip vias have been described in the exemplary embodiments of the present invention. However, address transfer through-chip vias which are vertically formed through the respective slave chips and configured to transfer an address, command transfer through-chip vias for transferring a command, and power transfer through-chip vias for transferring power may be provided.

What is claimed is:

1. A semiconductor integrated circuit comprising:
a plurality of slave chips each comprising:
a core area comprising a memory cell array;
a global data line configured to transfer input/output data of the corresponding core area; and
a first peripheral circuit area configured to interface the corresponding core area and the corresponding global data line;
a plurality of data transfer through-chip vias vertically formed through the plurality of slave chips, respectively, and coupled to the respective global data lines of the slave chips; and
a master chip comprising a second peripheral circuit area configured to provide an input/output interface between the data transfer through-chip vias and an external controller.

2. The semiconductor integrated circuit of claim 1, wherein each of the slave chips does not comprise the second peripheral circuit area.

3. The semiconductor integrated circuit of claim 2, wherein the first peripheral circuit areas each comprise:
a sense amplification unit configured to amplify data loaded onto a local data line of the corresponding core area and transfer the amplified data to the corresponding global data line; and
a write driver configured to drive the corresponding local data line in response to the data loaded onto the corresponding global data line.

4. The semiconductor integrated circuit of claim 3, wherein each of the slave chips further comprises a third peripheral circuit area having a test circuit configured to test the corresponding core area and the corresponding first peripheral circuit area.

5. The semiconductor integrated circuit of claim 4, wherein the test circuits each comprise a built-in self test (BIST) circuit.

6. The semiconductor integrated circuit of claim 1, wherein the second peripheral circuit area comprises:
a data pad coupled to the external controller;
an input circuit comprising:
an input buffer unit configured to buffer data inputted through the data pad;
a prefetch unit configured to prefetch the data buffered by the input buffer unit; and
an amplification unit configured to amplify the data prefetched by the prefetch unit and output the amplified data to at least one of the plurality of data transfer through-chip vias; and
an output circuit comprising:
a pipe latch unit configured to latch data received through at least one of the plurality of data transfer through-chip vias; and
an output driver configured to output the data latched in the pipe latch unit to the data pad.

7. The semiconductor integrated circuit of claim 6, wherein the second peripheral circuit area further comprises:
a power unit configured to output power; and
a state machine configured to process an address and command inputted from the external controller.

8. The semiconductor integrated circuit of claim 7, wherein the master chip further comprises a fourth peripheral circuit area having a test circuit configured to test the second peripheral circuit area.

9. The semiconductor integrated circuit of claim 1, further comprising:
a plurality of address transfer through-chip vias vertically formed through the respective slave chips and configured to transfer an address between the plurality of slave chips and the master chip; and
a plurality of command transfer through-chip vias vertically formed through the respective slave chips and configured to transfer a command between the plurality of slave chips and the master chip.

10. The semiconductor integrated circuit of claim 9, wherein the plurality of data transfer through-chip vias, the plurality of address transfer through-chip vias, and the plurality of command transfer through-chip vias are through silicon vias (TSV).

11. A semiconductor integrated circuit comprising:
a plurality of slave chips each comprising:
a first core area comprising a memory cell array;
a first global data line configured to transfer input/output data of the corresponding first core area; and
a first peripheral circuit area configured to interface the corresponding first core area with the corresponding first global data line;
a plurality of data transfer through-chip vias vertically formed through the plurality of slave chips, respectively, and coupled to the respective global data lines of the slave chips; and
a master chip comprising:
a second core area comprising a memory cell array;
a second global data line configured to transfer input/output data of the second core area;
a second peripheral circuit area configured to interface the second core area with the second global data line; and
a third peripheral circuit area configured to provide an input/output interface between the second global data line and an external controller and an input/output interface between the plurality of data transfer through-chip vias and the external controller,
wherein each of the slave chips does not comprise the third peripheral circuit area.

12. The semiconductor integrated circuit of claim 11, wherein the first peripheral circuit areas each comprise:
a sense amplification unit configured to amplify data loaded onto a local data line of the corresponding first core area and transfer the amplified data to the corresponding first global data line; and
a write driver configured to drive the corresponding local data line in response to the data loaded onto the corresponding first global data line.

13. The semiconductor integrated circuit of claim 12, wherein each of the slave chips further comprises a fourth peripheral circuit area having a test circuit configured to test the corresponding first core area and the corresponding first peripheral circuit area.

14. The semiconductor integrated circuit of claim 13, wherein the test circuits each comprise a built-in self test (BIST) circuit.

15. The semiconductor integrated circuit of claim 11, wherein the second peripheral circuit area comprises:
a sense amplification unit configured to amplify data loaded onto a local data line of the second core area and transfer the amplified data to the second global data line; and
a write driver configured to drive the local data line of the second core area in response to the data loaded onto the second global data line.

16. The semiconductor integrated circuit of claim 11, wherein the third peripheral circuit area comprises:
a data pad coupled to the external controller;
an input circuit comprising:
an input buffer unit configured to buffer data inputted through the data pad;
a prefetch unit configured to prefetch the data buffered by the input buffer unit; and
an amplification unit configured to amplify the data prefetched by the prefetch unit and output the amplified data to at least one of the plurality of data transfer through-chip vias or the second global data line; and
an output circuit comprising:
a pipe latch unit configured to latch data received through at least one of the plurality of data transfer through-chip vias or the second global data line; and
an output driver configured to output the data latched in the pipe latch unit to the data pad.

17. The semiconductor integrated circuit of claim 16, wherein the third peripheral circuit area further comprises:
a power unit configured to output power; and
a state machine configured to process an address and command inputted from the external controller.

18. The semiconductor integrated circuit of claim 17, wherein the master chip further comprises a fourth peripheral circuit area having a test circuit configured to test the second core area, the second peripheral circuit area, and the third peripheral circuit area.

19. The semiconductor integrated circuit of claim 11, further comprising:
a plurality of address transfer through-chip vias vertically formed through the respective slave chips and configured to transfer an address between the plurality of slave chips and the master chip; and
a plurality of command transfer through-chip vias vertically formed through the respective slave chips and configured to transfer a command between the plurality of slave chips and the master chip.

20. The semiconductor integrated circuit of claim 19, wherein the plurality of data transfer through-chip vias, the plurality of address transfer through-chip vias, and the plurality of command transfer through-chip vias are through silicon vias (TSV)s.

21. A semiconductor integrated circuit comprising:
a master chip comprising a master peripheral circuit area; and
a slave chip, stacked onto the master chip, comprising:
a core area comprising a memory cell array;
a global data line configured to transfer input/output data of the core area; and
a slave peripheral circuit area configured to interface the core area and the global data line; and
a data transfer through-chip via vertically formed through the slave chip, and coupled to the global data line of the slave chip,
wherein the area of the master peripheral circuit area is greater than the area of the slave peripheral circuit area.

22. A method for fabricating a semiconductor integrated circuit comprising:
forming a master chip, comprising a master peripheral circuit area, using a master chip mask;
forming a slave chip, comprising a core area and a slave peripheral circuit area, using a slave chip mask; and
stacking the slave chip onto the master chip;
wherein the area of the slave peripheral circuit area is greater than the area of the master peripheral circuit area.
